(19) United States
(12) Patent Application Publication
(10) Pub. No.: US 2026/0243845 A1
(43) Pub. Date: Aug. 20, 2026

(54) Techniques For Detecting Bandgap And Supply Voltages During Power-On-Reset

(71) Applicant: Altera Corporation, San Jose, CA (US)

(72) Inventors: Maneesha Yellepeddi, Los Gatos, CA (US); Kalyana Kantipudi, San Jose, CA (US); Ping Xiao, East Palo Alto, CA (US); Ching Sia Lim, Timur Laut (MY); Sermalingam Chandrasekaran, Bayan Lepas (MY); Ahmad Samhan Mohamed Aslam, Kuala Lumpur (MY)

(73) Assignee: Altera Corporation, San Jose, CA (US)

(21) Appl. No.: 19/056,536

(22) Filed: Feb. 18, 2025

(51) Int. Cl. G01R 31/40; G01R 19/165

(52) U.S. Cl. CPC G01R 31/40; G01R 19/16519

(57) ABSTRACT

A test power-on-reset detector circuit includes a trip-out detector circuit that generates a trip-out signal indicative of a supply voltage increasing above a trip-out level and a trip-in detector circuit that generates a trip-in signal indicative of the supply voltage decreasing below a trip-in level that is less than the trip-out level. The test power-on-reset detector circuit includes a latch circuit that stores values of the trip-out signal and of the trip-in signal to generate a power-on-reset signal during a test of an integrated circuit to control functional power-on-reset signals. A bandgap reference voltage detector circuit includes an amplifier circuit that amplifies a difference between voltages as offset by a first voltage skew to control a current that affects the voltages. A comparator circuit compares the voltages as offset by a second voltage skew to generate a voltage that indicates when a bandgap reference voltage is stable.

### BACKGROUND

Configurable integrated circuits (ICs) can be configured by users to implement desired custom logic functions. In a typical scenario, a logic designer uses computer-aided design (CAD) tools to design a custom circuit design. When the design process is complete, the computer-aided design tools generate an image containing configuration data bits. The configuration data bits are then loaded into configuration memory elements that configure configurable logic circuits in the integrated circuit to perform the functions of the custom circuit design.

### BRIEF DESCRIPTION OF DRAWINGS

FIG. 1 is a diagram that illustrates an example of a bandgap reference voltage generator circuit that includes a core bandgap reference voltage circuit and a bandgap output circuit.

FIG. 2 is a timing diagram that illustrates examples of waveforms of four voltages in the bandgap reference voltage generator circuit of FIG. 1.

FIG. 3 is a diagram that illustrates an example of a bandgap reference voltage detector circuit that can accurately track the bandgap reference voltage generated by the bandgap reference voltage generator circuit of FIG. 1 during power-up and power-down of an integrated circuit.

FIG. 4 is a timing diagram that illustrates examples of waveforms of four voltages in bandgap reference voltage detector circuit of FIG. 3.

FIG. 5 is a diagram that illustrates an example of a test power-on-reset (POR) detector circuit in an integrated circuit (IC).

FIG. 6 is a diagram that illustrates an example of a secure device manager (SDM) circuit in an integrated circuit (IC) that includes the test POR detector circuit of FIG. 5.

FIG. 7 is a timing diagram that illustrates examples of waveforms for various voltages in the secure device manager (SDM) circuit of FIG. 6.

FIG. 8 is a diagram of an illustrative example of a configurable integrated circuit (IC).

FIG. 9A illustrates a block diagram of a system that can be used to implement a circuit design to be programmed into a programmable logic device using design software.

FIG. 9B is a diagram that depicts an example of a programmable logic device that includes fabric dies and base dies that are coupled to one another via microbumps.

FIG. 10 is a block diagram illustrating a computing system configured to implement one or more aspects of the embodiments described herein.

### DETAILED DESCRIPTION

Some types of configurable integrated circuits (ICs) use voltage reference based Power-On-Reset (POR) detection for reliable and secure device configuration upon power-up and power-down of the configurable ICs. The validity of the POR detection highly depends on the readiness and accuracy of the reference voltage. The reference voltage is usually generated with an on-die bandgap reference circuit that is powered by a device analog power rail. The level of the power rail at which the bandgap reference circuit output becomes stable and ready upon power-up and power-down varies with process, supply voltage, and temperature of each integrated circuit (IC). Because many configurable ICs support a power-up and power-down sequence free operation, and a known always-on power rail may not be available, it is important to autonomously indicate the quality of the bandgap reference voltage, without information about the quality of the power rail.

According to some examples disclosed herein, a bandgap reference voltage detector circuit is provided in an integrated circuit (IC). The bandgap reference voltage detector circuit can accurately track a bandgap reference voltage generated by a bandgap reference voltage generator circuit during power-up and power-down of the IC. The bandgap reference voltage detector circuit generates an output that indicates when the bandgap reference voltage is stable and ready to be used across variations in the process, supply voltage, and temperature (PVT) of the IC. The bandgap reference voltage detector circuit includes an error amplifier having a differential input pair of transistors that have a voltage skew. The bandgap reference voltage detector circuit also includes a comparator circuit that compares voltages received at the differential input pair of transistors in the error amplifier. The voltage skew of the error amplifier causes the bandgap reference voltage detector circuit to closely track the operation of the bandgap reference voltage generator circuit during the power-up and power-down of the IC. The bandgap reference voltage detector circuit generates an output that changes state when the bandgap reference voltage is within a percentage (e.g., less than 2%) of a target voltage over PVT variation in the IC.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers'specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the terms “connected” and “connection” mean a direct electrical connection between the circuits that are connected, without any intermediary devices. The terms “coupled” and “coupling” mean either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

This disclosure discusses integrated circuit devices, including configurable (programmable) integrated circuits, such as field programmable gate arrays (FPGAs) and programmable logic devices. As discussed herein, an integrated circuit (IC) can include hard logic and/or soft logic. The circuits in an integrated circuit device (e.g., in a configurable IC) that are configurable by an end user are referred to as “soft logic.” “Hard logic” generally refers to circuits in an integrated circuit device that have substantially less configurable features than soft logic or no configurable features.

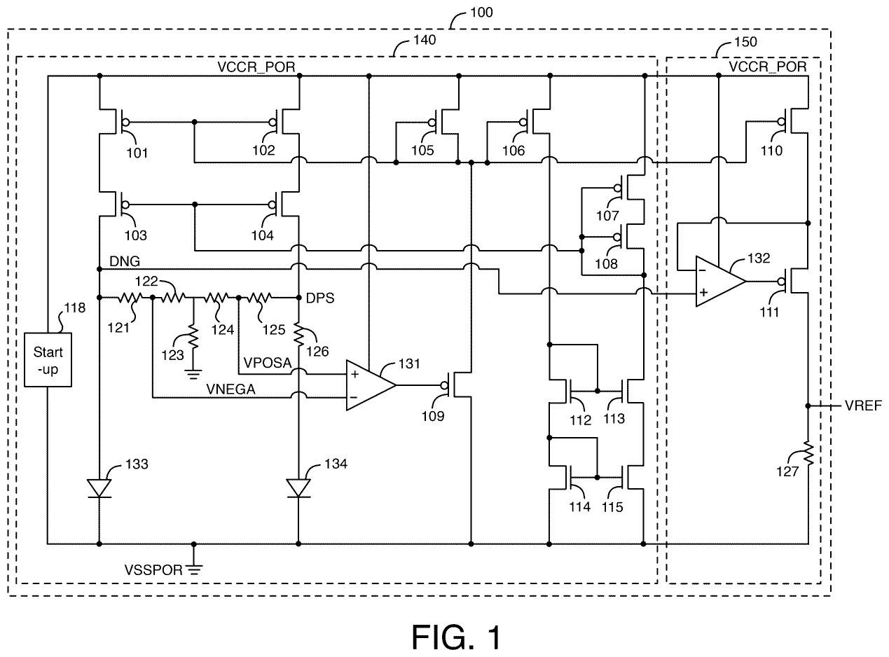

FIG. 1 is a diagram that illustrates an example of a bandgap reference voltage generator circuit 100 that includes a core bandgap reference voltage circuit 140 and a bandgap output circuit 150. The core bandgap reference voltage circuit 140 includes 9 p-channel field-effect transistors (FETs) 101-109, 4 n-channel FETs 112-115, a start-up circuit 118, 6 resistors 121-126, an amplifier circuit 131, and 2 diodes 133-134. The bandgap output circuit 150 includes p-channel FETs 110-111, amplifier circuit 132, and a resistor 127. The FETs 101-115 can be, for example, MOSFETs (i.e., metal oxide semiconductor field-effect transistors). The bandgap reference voltage generator circuit 100 can be formed in any type of integrated circuit (IC), such as a configurable IC (e.g., a field programmable gate array (FPGA) or programmable logic device (PLD)), a microprocessor IC, a graphics processing unit IC, a memory IC, an application specific IC, a transceiver IC, etc. In the examples disclosed herein, the circuitry, methods, and systems are described in the context of a configurable IC, such as an FPGA or PLD merely for the purpose of illustration.

The bandgap reference voltage generator circuit 100 receives a supply voltage VCCR_POR at a supply rail. The bandgap output circuit 150 generates a bandgap reference voltage VREF at an output between the drain of p-channel transistor 111 and resistor 127. The core bandgap reference voltage circuit 140 generates voltages DNG and DPS at the drains of p-channel transistors 103 and 104, respectively. According to an example, the size of diode 134 equals N multiplied by the size of diode 133, where N is a positive integer greater than 1. In this example, the voltage DNG equals the voltage across diode 133, and the voltage DPS=(VD133×N)+(R126×N×ID133), where VD133 equals the voltage across diode 133, R126 is the resistance of resistor 126, and ID133 is the current through diode 133. N may be, for example, equal to 8.

Voltage VNEGA is a scaled down version of voltage DNG using resistors 121-125, and voltage VPOSA is a scaled down version of voltage DPS using resistors 121-125. Voltages VPOSA and VNEGA are provided to the positive and negative inputs of amplifier circuit 131, respectively. Amplifier circuit 131 controls the current through transistor 109. The current through transistor 109 controls the voltage at the gates of transistors 101-102 and 105-106. The current through transistor 106 controls the currents through transistors 112-115 and 107-108. The current through transistors 107-108, 113, and 115 controls the voltage at the gates of transistors 103-104. The currents through transistors 101-104 controls the voltages DNG and DPS. Voltage DNG is provided to the positive input of amplifier circuit 132, and the negative input of amplifier circuit 132 is coupled between the drain of transistor 110 and the source of transistor 111. Amplifier circuit 132 controls the current through transistor 111.

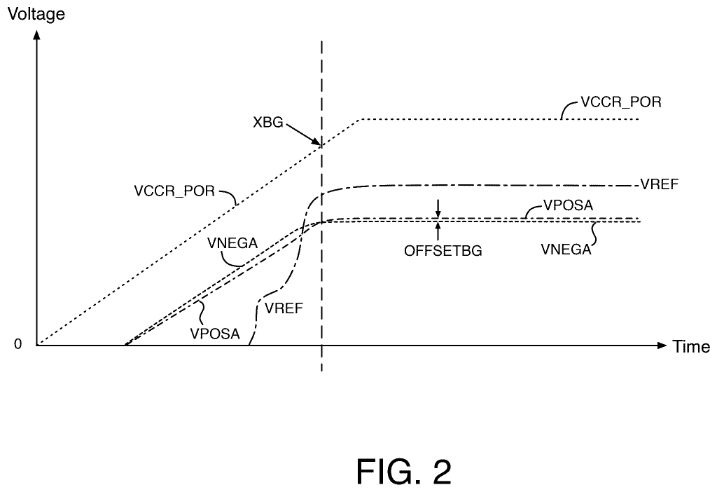

FIG. 2 is a timing diagram that illustrates examples of waveforms of four voltages VCCR_POR, VNEGA, VPOSA, and VREF in the bandgap reference voltage generator circuit 100 of FIG. 1. Upon power-up of the IC containing bandgap reference voltage generator circuit 100, the currents through diodes 133-134 are initially at 0 amperes (Amps), and the current mirror circuit formed by p-channel transistors 101-104 attempts to force equal current through diodes 133 and 134, causing the voltage VNEGA to be greater than voltage VPOSA, as shown in FIG. 2. As the supply voltage VCCR_POR provided to the bandgap reference voltage generator circuit 100 ramps up to its maximum nominal voltage, and the current through diodes 133-134 increases, the voltage VPOSA increases, causing the difference between voltages VNEGA and VPOSA (VNEGA−VPOSA) to decrease. VPOSA increases above VNEGA when the supply voltage VCCR_POR reaches a bandgap stable voltage level XBG, as shown in FIG. 2, and the amplifier circuit 131 generates a voltage level at the gate of transistor 109 that causes the current mirror circuit formed by transistors 101-104 to lock and maintain a bandgap stable state. In the bandgap stable state, the bandgap output circuit 150 generates a stable and constant reference voltage VREF, when the voltage VPOSA is slightly greater than voltage VNEGA, within a minimum offset voltage (OFFSETBG) maintained over PVT of the IC, as shown in Figure (FIG.) 2.

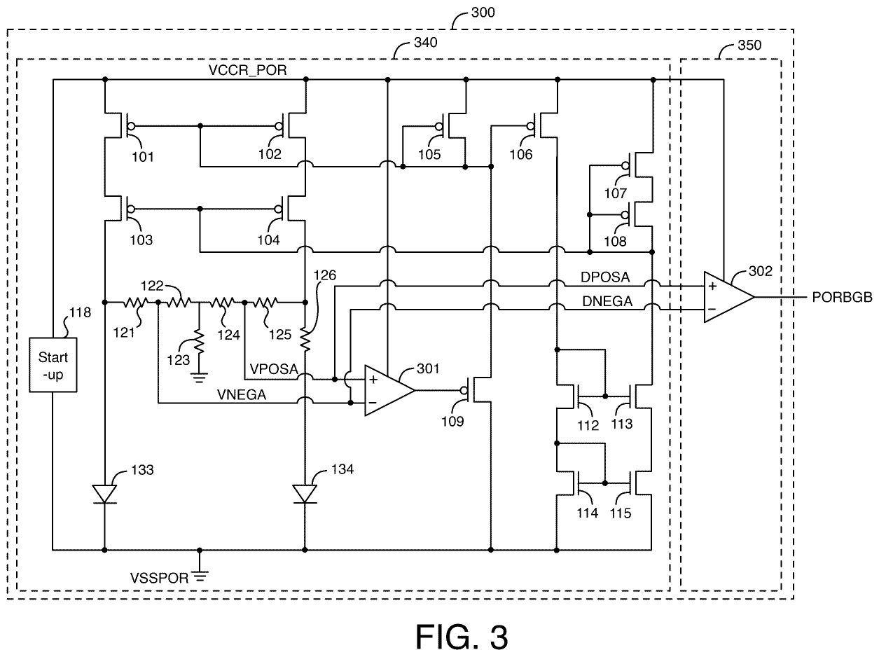

FIG. 3 is a diagram that illustrates an example of a bandgap reference voltage detector circuit 300 that can accurately track the bandgap reference voltage VREF generated by the bandgap reference voltage generator circuit 100 of FIG. 1 during power-up and power-down of the IC. The bandgap reference voltage detector circuit 300 generates an output voltage PORBGB that indicates when the bandgap reference voltage VREF is stable and ready to be used as a stable reference voltage in the IC across variations in the process, supply voltage, and temperature (PVT) of the IC. The bandgap reference voltage detector circuit 300 can be formed in any type of integrated circuit (IC), such as a configurable IC (e.g., a field programmable gate array (FPGA) or programmable logic device (PLD)), a microprocessor IC, a graphics processing unit IC, a memory IC, an application specific IC, a transceiver IC, etc.

The bandgap reference voltage detector circuit 300 includes a replica bandgap core circuit 340 and an output comparison circuit 350 that both receive the same supply voltage VCCR_POR provided to bandgap reference voltage generator circuit 100. The replica bandgap core circuit 340 includes all of the circuitry in the core bandgap reference voltage circuit 140 of FIG. 1, except the amplifier circuit 131. Thus, the replica bandgap core circuit 340 includes p-channel field-effect transistors (FETs) 101-109, n-channel FETs 112-115, start-up circuit 118, resistors 121-126, and diodes 133-134. The replica bandgap core circuit 340 also includes an amplifier circuit 301.

Voltages VPOSA and VNEGA are provided from the resistors 121-125 to the positive and negative inputs of amplifier circuit 301, respectively. Amplifier circuit 301 functions as an error amplifier. The amplifier circuit 301 has a differential input pair of transistors that have a voltage skew. Amplifier circuit 301 amplifies the voltage difference between voltages VPOSA and VNEGA as offset by the voltage skew to generate an output voltage that controls the current through transistor 109. As discussed above with respect to FIG. 1, the current through transistor 109 controls the gate voltages of, and the currents through, transistors 101-102 and 105-106, which control the voltages VPOSA and VNEGA.

The output comparison circuit 350 in bandgap reference voltage detector circuit 300 includes a comparator circuit 302. Voltages VPOSA and VNEGA are also provided from the resistors 121-125 to the positive and negative inputs of comparator circuit 302, respectively. The comparator circuit 302 compares the voltages VPOSA and VNEGA to generate an output voltage PORBGB that indicates when the bandgap reference voltage VREF is stable and ready to be used as a stable reference voltage in the IC, for example, after a power-on-reset (POR) in the IC. Comparator circuit 302 also has a voltage skew. The voltage skews in amplifier circuit 301 and in comparator circuit 302 cause bandgap reference voltage detector circuit 300 to closely track the operation of bandgap reference voltage generator circuit 100 during the power-up and power-down of the IC.

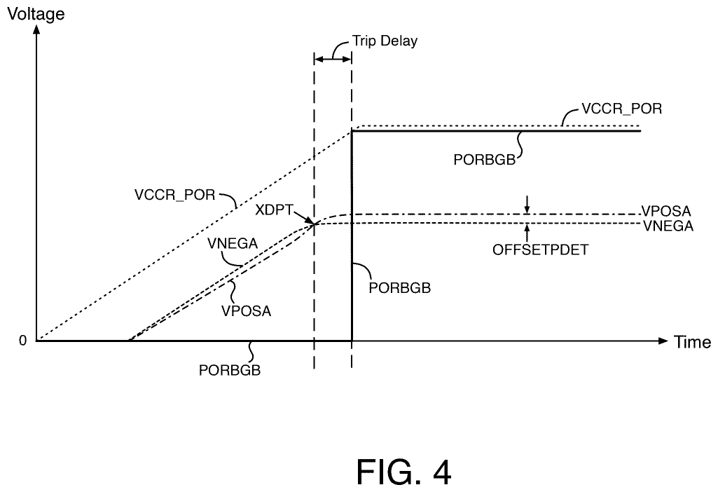

FIG. 4 is a timing diagram that illustrates examples of waveforms of four voltages VCCR_POR, VNEGA, VPOSA, and PORBGB in bandgap reference voltage detector circuit 300 of FIG. 3. The replica bandgap core circuit 340 in the bandgap reference voltage detector circuit 300 tracks the operation of the bandgap reference voltage generator circuit 100 closely. For example, voltages VPOSA and VNEGA in the bandgap reference voltage detector circuit 300 cross each other at point XDPT in the example of FIG. 4, which corresponds to the same supply voltage level of VCCR_POR where voltages VPOSA and VNEGA cross each other in the bandgap reference voltage generator circuit 100 of FIG. 1, as shown by point XBG in FIG. 2.

However, the bandgap reference voltage detector circuit 300 has a larger stabilized offset voltage OFFSETPDET between voltages VPOSA and VNEGA, as shown in FIG. 4, because of the intended voltage skew added in the input differential pair of transistors in amplifier circuit 301. The larger offset voltage OFFSETPDET between voltages VPOSA and VNEGA ensures a solid trip point of the output voltage PORBGB of the comparator circuit 302 when the supply voltage VCCR_POR increases to a voltage level that causes voltages VPOSA and VNEGA to cross each other at point XDPT over variations in PVT.

FIG. 4 shows an example of the output voltage PORBGB of comparator circuit 302 changing from zero volts to a higher voltage in response to voltage VPOSA equaling and/or increasing above the voltage VNEGA at point XDPT. The output voltage PORBGB of comparator circuit 302 changes from zero volts to a higher voltage, in the example shown in FIG. 4, a Trip Delay after voltage VPOSA equals and/or exceeds voltage VNEGA at point XDPT. The Trip Delay shown in FIG. 4 is caused by the voltage skew in the input differential pair of transistors in comparator circuit 302. The voltage skew in the input differential pair of transistors in comparator circuit 302 provides a means to fine tune the final trip level of the output voltage PORBGB as needed.

The stabilized voltage levels of voltages VPOSA and VNEGA in the replica bandgap core circuit 340 are very close to the voltages VPOSA and VNEGA in the bandgap reference voltage generator circuit 100 of FIG. 1 to ensure that the currents flowing through diodes 133-134 are similar to the currents in bandgap reference voltage generator circuit 100 and are within the limits of the semiconductor process requirements.

As a result, bandgap reference voltage detector circuit 300 generates an output voltage PORBGB that indicates when the bandgap reference voltage VREF generated by bandgap reference voltage generator circuit 100 is stable and ready to be used as a stable reference voltage in the IC across variations in the process, supply voltage, and temperature (PVT) of the IC. The bandgap reference voltage detector circuit 300 tracks the power-up and the power-down operation of bandgap reference voltage generator circuit 100 and generates an accurate bandgap reference voltage readiness indicator (PORBGB) that varies with PVT of the IC.

Many configurable integrated circuits (ICs) use a power-on-reset (POR) circuit that generates a power-on-reset (POR) signal with a trip level that reflects operation levels for reliable and correct configuration upon power-up and for safe operation in user mode. However, during manufacturing of a configurable IC, the power supply level can go lower than the POR trip level, such as during high-speed test activity on a wafer die or a packaged unit without proper power decoupling, during an intended low voltage test, during characterization, or during a POR related debug caused by the POR circuit being triggered. The POR signal is disabled in these situations for reliable and successful device tests, device characterization, and device debugging.

According to some examples disclosed herein, a power-on-reset (POR) detector circuit in an IC monitors a POR supply voltage. The POR detector circuit generates a separate POR signal during manufacturing of the IC that has a lower trip-in level than the functional POR trip level used during user mode of the IC. The POR detector circuit enables the POR supply voltage to be lowered below the functional POR trip level for power-on-reset during low voltage testing and debugging of the IC, e.g., using test data registers.

The POR detector circuit is responsive to a trip-out level that corresponds to a voltage at which the POR detector circuit indicates that the POR supply voltage is good on power up of the IC. The POR detector circuit is responsive to a trip-in level that corresponds to a voltage at which the POR detector circuit indicates that the POR supply voltage is not good. The trip-in level of the POR detector circuit can be designed to be very close to the transistor threshold voltage level in the IC. The POR detector circuit provides a reset signal in response to a large droop in the POR supply voltage, a brownout, a power-down of the IC, or in the case of manufacturing, an intentional lowering of the POR supply voltage level for testing. The trip level can refer to either of these situations.

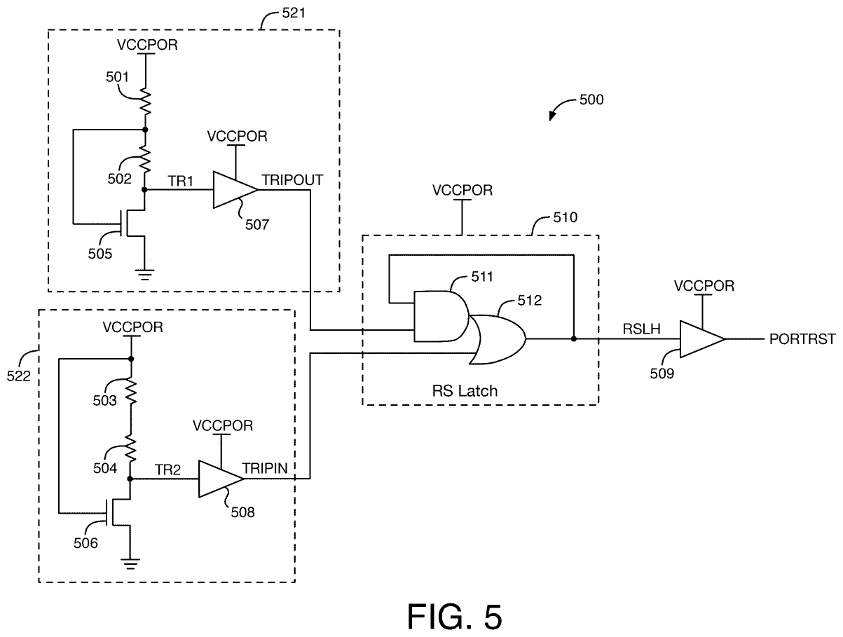

FIG. 5 is a diagram that illustrates an example of a test power-on-reset (POR) detector circuit 500 in an integrated circuit (IC). The test power-on-reset (POR) detector circuit 500 can be formed in any type of integrated circuit (IC), such as a configurable IC (e.g., an FPGA or PLD), a microprocessor IC, a graphics processing unit IC, a memory IC, an application specific IC, a transceiver IC, etc. Test POR detector circuit 500 includes 4 resistors 501-504, 2 n-channel FETs 505-506, 3 buffer circuits 507-509, and a reset-set (RS) latch circuit 510 that includes an AND logic gate circuit 511 and an OR logic gate circuit 512.

Resistors 501-502, transistor 505, and buffer circuit 507 are coupled to form a trip-out detector circuit 521. Resistors 503-504, transistor 506, and buffer circuit 508 are coupled to form a trip-in detector circuit 522. Resistor 501, resistor 503, and RS latch circuit 510 are coupled to a supply rail at a POR supply voltage VCCPOR. Supply voltage VCCPOR is also provided to power each of the buffer circuits 507-509, AND gate circuit 511, and OR gate circuit 512. The gate of transistor 505 is couped between resistors 501-502. The gate of transistor 506 is coupled between resistor 503 and the supply rail at supply voltage VCCPOR.

The trip-out voltage TR1 at the drain of transistor 505 is provided to an input of buffer circuit 507. The trip-in voltage TR2 at the drain of transistor 506 is provided to an input of buffer circuit 508. The output voltage TRIPOUT of buffer circuit 507 is provided to a first input of AND logic gate circuit 511, and the output voltage TRIPIN of buffer circuit 508 is provided to a first input of OR logic gate circuit 512. The output voltage of OR logic gate circuit 512 is provided to a second input of AND logic gate circuit 511 and to an input of buffer circuit 509. The output voltage of AND logic gate circuit 511 is provided to a second input of OR logic gate circuit 512.

The threshold voltage of transistor 505 and resistors 501-502 set the trip-out voltage TR1 of trip-out detector circuit 521, and the threshold voltage of transistor 506 sets the trip-in voltage TR2 of trip-in detector circuit 522. The trip-out voltage TR1 is adjustable by varying the resistor ratio of resistors 501-502. The resistor ratio of the resistors 501-502 in the trip-out detector circuit 521 are designed to ensure a solid power-on-reset upon power-up of the IC. The gate of n-channel transistor 506 in trip-in detector circuit 522 is coupled to the supply rail at supply voltage VCCPOR to ensure a minimum possible trip-in level with a maximum supply voltage VCCPOR range for functional POR signal gating control during device test or debugging in manufacturing.

Buffer circuit 507 buffers the trip-out voltage TR1 to generate voltage TRIPOUT, and buffer circuit 508 buffers the trip-in voltage TR2 to generate voltage TRIPIN. The trip-out detector circuit 521 asserts the voltage TRIPOUT from a higher voltage to a low voltage in response to transistor 505 turning on when the supply voltage VCCPOR exceeds a trip-out level. The trip-in detector circuit 522 asserts the voltage TRIPIN from a low voltage to a higher voltage (VCCPOR) in response to transistor 506 turning off when the supply voltage VCCPOR decreases below the trip-in level.

The RS latch circuit 510 stores the values of the output voltage TRIPOUT of trip-out detector circuit 521 and the values of the output voltage TRIPIN of the trip-in detector circuit 522 to generate an output voltage RSLH that is provided to buffer circuit 509. Buffer circuit 509 buffers the output voltage RSLH of RS latch circuit 510 to generate a final output voltage PORTRST that has a high trip-out level and a lower trip-in level for controlling the power-on-reset in the IC (e.g., during low voltage testing or debugging).

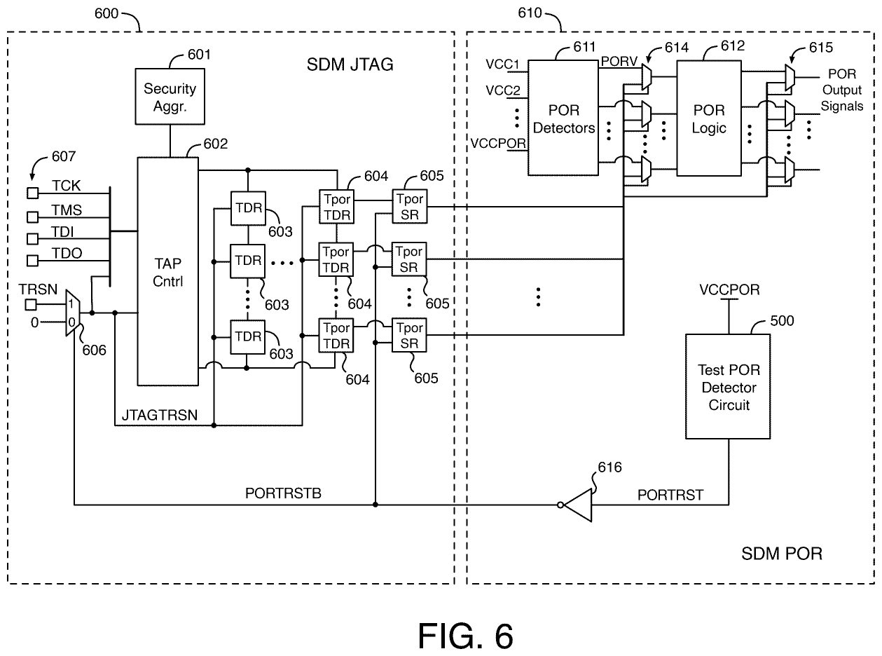

FIG. 6 is a diagram that illustrates an example of a secure device manager (SDM) circuit in an integrated circuit (IC) that includes the test POR detector circuit 500 of FIG. 5. The IC of FIG. 6 may, for example, be a configurable IC. The SDM circuit of FIG. 6 includes an SDM Joint Test Action Group (JTAG) circuit 600 and an SDM power-on-reset (POR) circuit 610. The SDM JTAG circuit 600 includes a security aggregator circuit 601, a test access port (TAP) controller (Cntrl) circuit 602, test data register (TDR) circuits 603, JTAG accessible test POR (Tpor) test data register (TDR) circuits 604, test POR shadow register (SR) circuits 605, multiplexer circuit 606, and external pads 607 of a JTAG port. SDM POR circuit 610 includes POR detector circuits 611, POR logic circuits 612, multiplexer circuits 614, multiplexer circuits 615, inverter circuit 616, and test POR detector circuit 500 of FIG. 5.

SDM POR circuit 610 includes a functional POR module that detects a group of power supply voltages VCC1, VCC2, VCCPOR, etc. of the IC and generates a group of POR output signals for the power-on-reset of the IC. The test POR detector circuit 500 detects the power supply voltage VCCPOR to generate the output voltage PORTRST, as described above with respect to FIG. 5, for JTAG and for the TDR circuits during power-on-reset of the IC. The output voltage PORTRST is inverted by inverter circuit 616 to generate an inverted voltage PORTRSTB that is provided to a select input of multiplexer circuit 606 and to an input of each of the test POR shadow register circuits 605.

The TAP controller circuit 602 is controlled by the security aggregator circuit 601. Multiplexer circuit 606 provides test POR control data indicated by signal TRSN via signal JTAGTRSN to TDR circuits 603-604 in normal operation. The test POR shadow register (SR) circuits 605 store the test POR control data that are shifted into the test POR TDR circuits 604 through JTAG signal JTAGTRSN.

During power-up of the IC, the test POR detector circuit 500 asserts the PORTRST signal to a high voltage, causing inverter circuit 616 to generate a low voltage in the PORTRSTB signal that causes multiplexer circuit 606 to provide a logic 0 in signal JTAGTRSN to TDR circuits 603 and to test POR TDR circuits 604. The TDR circuits 603 and the test POR TDR circuits 604 are reset in response to the logic 0 in signal JTAGTRSN during power-up. The test POR shadow register circuits 605 are reset in response to the low voltage in signal PORTRSTB generated by inverter circuit 616 in response to the high voltage in signal PORTRST generated by detector circuit 500. In response to default test POR values stored in test POR TDR circuits 604 and in shadow register circuits 605, multiplexer circuits 614 provide functional POR values (PORV) output by POR detector circuits 611 to POR logic circuits 612, and POR logic circuits 612 provide these functional POR values through multiplexer circuits 615 to the POR output signals during normal power-on reset functionality.

During low voltage testing or debugging of the IC, the IC is powered on in normal functional mode. The test POR TDR circuits 604 are set through JTAG (e.g., using TAP controller circuit 602 or multiplexer circuit 606) to override the default test POR values mentioned above and to update the values stored in the test POR shadow register circuits 605. The properly set values stored in the test POR shadow register circuits 605 cause the multiplexer circuits 614-615 to override and/or to block the functional POR values output by POR detector circuits 611, regardless of the detection result of the POR detector circuits 611. Instead, the multiplexers circuits 614-615 provide the values stored in the test POR shadow register circuits 605 to the POR output signals. As a result, the lowered and/or disturbed device power supply voltages VCC1, VCC2, etc. do not impact the operation of the IC.

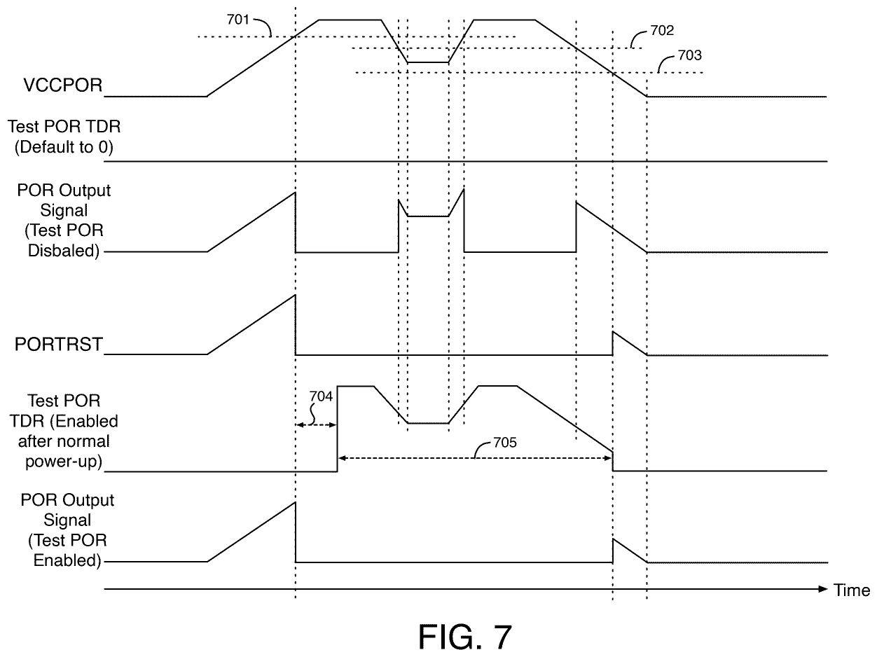

FIG. 7 is a timing diagram that illustrates examples of waveforms for various voltages in the secure device manager (SDM) circuit of FIG. 6, including in the test power-on-reset (POR) detector circuit 500 of FIG. 5. During the normal user mode of the IC, the values stored in the test POR TDR circuits 604 are reset in response to voltage PORTRST to the default values of 0. During the normal user mode of the IC when the test power-on-reset (POR) functionality is disabled, the SDM POR circuit 610 of FIG. 6 decreases one of the POR output signals to zero volts each time that the supply voltage VCCPOR increases above the normal functional POR trip-out level 701, as shown in FIG. 7. Also, during the normal user mode of the IC when the test POR functionality is disabled, SDM POR circuit 610 increases one of the POR output signals to a higher voltage each time that the supply voltage VCCPOR decreases below the normal functional POR trip-in level 702, as shown in FIG. 7, using POR detector circuits 611 for user mode power-up of the IC and power monitoring.

During low voltage testing or debugging of the IC, the test power-on-reset (POR) functionality is enabled. When the test POR functionality is enabled, the test POR detector circuit 500 of FIG. 5 decreases voltage PORTRST to zero volts each time that the supply voltage VCCPOR increases above the test POR trip-out level 701, as shown in FIG. 7. Also, when the test POR functionality is enabled, the test POR detector circuit 500 increases voltage PORTRST from zero volts to a higher voltage (VCCPOR) each time that the supply voltage VCCPOR decreases below the test POR trip-in level 703, as shown in FIG. 7.

During low voltage testing or debugging of the IC, the values stored in the test POR TDR circuits 604 are power-on-reset in response to voltage PORTRST being set to default values through a normal power-up of the IC during time interval 704 shown in FIG. 7. The values stored in the test POR TDR circuits 604 are then set by JTAG in time interval 705 shown in FIG. 7 to enable the test POR functionality. In response to these values stored in the test POR TDR circuits 604, the multiplexer circuits 614-615 block the SDM POR circuit 610 from adjusting the POR output signal, during time interval 705 as shown in FIG. 7, to allow the IC to continue to operate even when the supply voltage VCCPOR is decreased below the functional POR trip-in level 702. The change in the supply voltage VCCPOR level does not impact the logic values stored in the test POR TDR circuits 604.

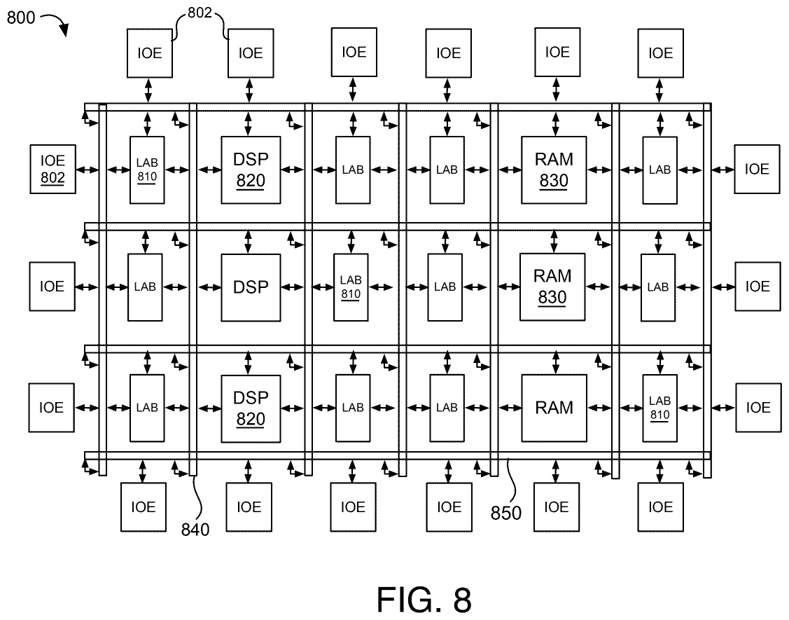

FIG. 8 is a diagram of an illustrative example of a configurable integrated circuit (IC) 800. Configurable IC 800 is an example of an IC that can include the circuits disclosed herein with respect to FIGS. 1, 3, 5, and 6, including bandgap reference voltage generator circuit 100, bandgap reference voltage detector circuit 300, test power-on-reset (POR) detector circuit 500, SDM JTAG circuit 600, and SDM POR circuit 610 of FIG. 6. As shown in FIG. 8, the configurable integrated circuit 800 includes a two-dimensional array of configurable logic circuit blocks, including logic array blocks (LABs) 810 and other configurable logic circuit blocks, such as random access memory (RAM) blocks 830 (e.g., BRAMs) and digital signal processing (DSP) blocks 820, for example. Configurable logic circuit blocks, such as LABs 810, can include smaller configurable regions (e.g., configurable logic elements, configurable logic blocks, or adaptive logic modules (ALMs)) that receive input signals and perform custom functions on the input signals to produce output signals.

The configurable integrated circuit 800 also includes programmable interconnect circuitry in the form of vertical routing channels 840 (i.e., interconnects formed along a vertical axis of configurable integrated circuit 800) and horizontal routing channels 850 (i.e., interconnects formed along a horizontal axis of configurable integrated circuit 800), each routing channel including at least one track to route at least one wire. One or more of the routing channels 840 and/or 850 can be part of a network-on-chip (NOC) having router circuits.

In addition, the configurable integrated circuit 800 has input/output elements (IOEs) 802 (e.g., including IO circuit blocks) for driving signals off of configurable integrated circuit 800 and for receiving signals from other devices. Input/output elements 802 can include parallel input/output circuitry, serial data transceiver circuitry, differential receiver and transmitter circuitry, or other circuitry used to connect one integrated circuit to another integrated circuit. Input/output elements 802 can include general purpose input/output (GPIO) circuitry (e.g., on the top and bottoms edges of IC 800), high-speed input/output (HSIO) circuitry (e.g., on the left edge of IC 800), and on-package input/output (OPIOs) circuitry (e.g., on the right edge of IC 800). The circuits disclosed herein with respect to FIGS. 1, 3, 5, and 6 can, for example, be placed in one or more of the IOEs 802.

As shown, input/output elements 802 can be located around the periphery of the IC. If desired, the configurable integrated circuit 800 can have input/output elements 802 arranged in different ways. For example, input/output elements 802 can form one or more columns of input/output elements that can be located anywhere on the configurable integrated circuit 800 (e.g., distributed evenly across the width of the configurable integrated circuit). If desired, input/output elements 802 can form one or more rows of input/output elements (e.g., distributed across the height of the configurable integrated circuit). Alternatively, input/output elements 802 can form islands of input/output elements that can be distributed over the surface of the configurable integrated circuit 800 or clustered in selected areas.

Note that other routing topologies, besides the topology of the interconnect circuitry depicted in FIG. 8, can be used. For example, the routing topology can include wires that travel diagonally or that travel horizontally and vertically along different parts of their extent as well as wires that are perpendicular to the device plane in the case of three dimensional integrated circuits, and the driver of a wire can be located at a different point than one end of a wire. The routing topology can include global wires that span substantially all of configurable integrated circuit 800, fractional global wires such as wires that span part of configurable integrated circuit 800, staggered wires of a particular length, smaller local wires, or any other suitable interconnection resource arrangement.

Furthermore, it should be understood that examples disclosed herein may be implemented in any type of integrated circuit. If desired, the functional blocks of such an integrated circuit can be arranged in more levels or layers in which multiple functional blocks are interconnected to form still larger blocks. Other device arrangements can use functional blocks that are not arranged in rows and columns.

Configurable integrated circuit 800 can also contain programmable memory elements. The memory elements can be loaded with configuration data (also called programming data) using input/output elements (IOEs) 802. Once loaded, the memory elements each provide a corresponding static control signal that controls the operation of an associated functional block (e.g., LABs 810, DSP 820, RAM 830, or input/output elements 802).

In a typical scenario, the outputs of the loaded memory elements are applied to the gates of field-effect transistors in a functional block to turn certain transistors on or off and thereby configure the logic in the functional block including the routing paths. Programmable logic circuit elements that are controlled in this way include parts of multiplexers (e.g., multiplexers used for forming routing paths in interconnect circuits), look-up tables, logic arrays, AND, OR, NAND, and NOR logic gates, pass gates, etc.

The memory elements can use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory or programmable memory elements.

The programmable memory elements can be organized in a configuration memory array consisting of rows and columns. A data register that spans across all columns and an address register that spans across all rows can receive configuration data. The configuration data can be shifted onto the data register. When the appropriate address register is asserted, the data register writes the configuration data to the configuration memory elements of the row that was designated by the address register.

Configurable integrated circuit 800 can include configuration memory that is organized in sectors, whereby a sector can include the configuration bits that specify the function and/or interconnections of the subcomponents and wires in or crossing that sector. Each sector can include separate data and address registers.

The configurable IC 800 of FIG. 8 is merely one example of an IC that can be used with embodiments disclosed herein. The embodiments disclosed herein can be used with any suitable electronic integrated circuit or system. For example, the embodiments disclosed herein can be used with numerous types of electronic devices such as processor integrated circuits, central processing units, memory integrated circuits, graphics processing unit integrated circuits, application specific standard products (ASSPs), application specific integrated circuits (ASICs), and configurable logic integrated circuits. Examples of configurable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

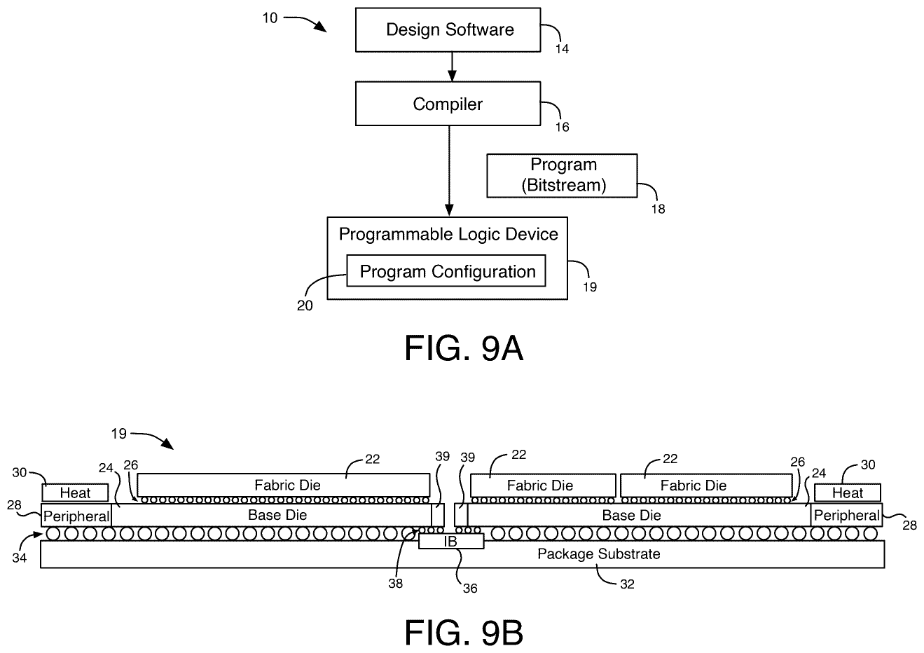

FIG. 9A illustrates a block diagram of a system 10 that can be used to implement a circuit design to be programmed onto a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized task.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 9B, but many others can be used, and it should be understood that this disclosure is intended to encompass any suitable programmable logic device where programmable logic fabric and fabric support circuitry are at least partially separated on different integrated circuit die.

FIG. 9B is a diagram that depicts an example of the programmable logic device 19 that includes three fabric die 22 and two base die 24 that are connected to one another via microbumps 26. In the example of FIG. 9B, at least some of the programmable logic fabric of the programmable logic device 19 is in the three fabric die 22, and at least some of the fabric support circuitry that operates the programmable logic fabric is in the two base die 24. For example, some of the circuitry of configurable IC 800 shown in FIG. 8 (e.g., LABs 810, DSP 820, and RAM 830) can be located in the fabric die 22 and some of the circuitry of IC 800 (e.g., input/output elements 802) can be located in the base die 24.

Although the fabric die 22 and base die 24 appear in a one-to-one relationship or a two-to-one relationship in FIG. 9B, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 9B, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

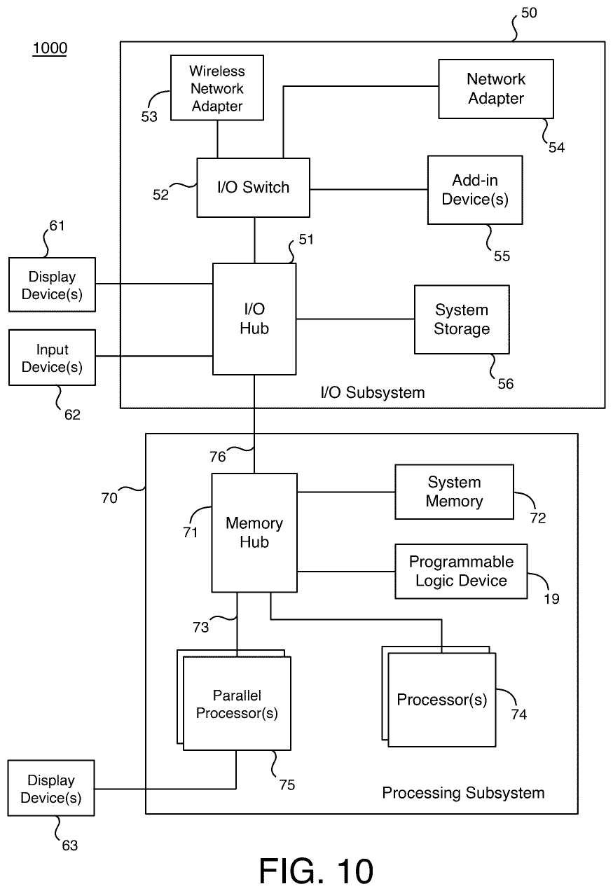

FIG. 10 is a block diagram illustrating a computing system 1000 configured to implement one or more aspects of the embodiments described herein. The computing system 1000 includes a processing subsystem 70 having one or more processor(s) 74, a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 1000 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 1000. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 1000 can include other components not shown in FIG. 10, including other port connections, optical storage drives, video capture devices, and the like, that can also be connected to the I/O hub 51. Communication paths interconnecting the various components in FIG. 10 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 1000 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 1000 can be integrated into a single package to form a system in package (SIP) configuration. In one embodiment, at least a portion of the components of the computing system 1000 can be integrated into a multi-chip module (MCM), which can be interconnected with other multi-chip modules into a modular computing system.

The computing system 1000 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 1000. For example, any number of add-in cards or peripherals can be supported, or some components can be eliminated. Furthermore, some architectures can use different terminology for components similar to those illustrated in FIG. 10. For example, the memory hub 71 can be referred to as a Northbridge in some architectures, while the I/O hub 51 can be referred to as a Southbridge.

Additional examples are now described. Example 1 is a bandgap reference voltage detector circuit comprising: an amplifier circuit that amplifies a difference between a first voltage and a second voltage as offset by a first voltage skew to control a current in the bandgap reference voltage detector circuit that affects the first voltage and the second voltage; and a comparator circuit that compares the first voltage to the second voltage as offset by a second voltage skew to generate a third voltage that indicates when a bandgap reference voltage is stable across variations in a process, a supply voltage, and a temperature of the bandgap reference voltage detector circuit.

In Example 2, the bandgap reference voltage detector circuit of Example 1 may optionally include, wherein the first voltage skew in the amplifier circuit causes the first voltage to differ from the second voltage after the third voltage indicates that the bandgap reference voltage is stable.

In Example 3, the bandgap reference voltage detector circuit of any one of Examples 1-2 may optionally include, wherein the third voltage generated by the comparator circuit changes from a first level to a second level a delay after the first voltage and the second voltage are equal, and wherein the delay is caused by the second voltage skew of the comparator circuit.

In Example 4, the bandgap reference voltage detector circuit of any one of Examples 1-3 may optionally include, wherein the comparator circuit causes the third voltage to indicate when the bandgap reference voltage is stable after a power-on-reset in an integrated circuit.

In Example 5, the bandgap reference voltage detector circuit of any one of Examples 1-4 may optionally include, wherein the bandgap reference voltage detector circuit is a power-on-reset detector circuit that indicates when the supply voltage provided to a bandgap reference voltage generator circuit and to the bandgap reference voltage detector circuit reaches a nominal value.

In Example 6, the bandgap reference voltage detector circuit of any one of Examples 1-5 may optionally include, wherein the bandgap reference voltage detector circuit is in a configurable integrated circuit.

In Example 7, the bandgap reference voltage detector circuit of Example 6 may optionally include, wherein the configurable integrated circuit comprises one of a monolithic die, multiple disaggregated dies, three dimensional dies, or 2.5 dimensional dies coupled through an interposer.

In Example 8, the bandgap reference voltage detector circuit of any one of Examples 1-7 may optionally include, wherein the bandgap reference voltage detector circuit enables circuitry in an integrated circuit that uses the bandgap reference voltage in response to the third voltage.

Example 9 is an integrated circuit comprising a test power-on-reset detector circuit, wherein the test power-on-reset detector circuit comprises: a trip-out detector circuit that generates a trip-out signal indicative of a supply voltage increasing above a trip-out level; a trip-in detector circuit that generates a trip-in signal indicative of the supply voltage decreasing below a trip-in level that is less than the trip-out level; and a latch circuit that stores values of the trip-out signal and of the trip-in signal to generate a power-on-reset signal during a test of the integrated circuit.

In Example 10, the integrated circuit of Example 9 may optionally include, wherein the trip-out detector circuit comprises a transistor and resistors coupled between the transistor and a supply rail at the supply voltage, wherein a gate of the transistor is coupled between the resistors, and wherein the trip-out signal is generated based on a voltage at a node between the transistor and the resistors.

In Example 11, the integrated circuit of any one of Examples 9-10 may optionally include, wherein the trip-in detector circuit comprises a transistor and resistors coupled between the transistor and a supply rail at the supply voltage, wherein a gate of the transistor is coupled to the supply rail, and wherein the trip-in signal is generated based on a voltage at a node between the transistor and the resistors.

In Example 12, the integrated circuit of any one of Examples 9-11 further comprises: functional power-on-reset detector circuits that generate power-on-reset values based on additional supply voltages in the integrated circuit; register circuits accessible through test inputs, wherein the register circuits are power-on-reset by the power-on-reset signal generated by the test power-on-reset detector circuit; and multiplexer circuits that are configurable to select and output either the power-on-reset values or output signals of the register circuits in response to selection values stored in the register circuits.

In Example 13, the integrated circuit of any one of Examples 9-12 further comprises: test data register circuits configurable to store test values during the test of the integrated circuit; shadow register circuits that are power-on-reset by the power-on-reset signal, wherein the shadow registers circuit store the test values received from the test data register circuits; and multiplexer circuits that provide the test values received from the shadow register circuits as power-on-reset output signals during the test.

In Example 14, the integrated circuit of any one of Examples 9-13 further comprises: a test access port controller circuit; test data register circuits configurable to store test values provided by the test access port controller circuit during the test of the integrated circuit; and multiplexer circuits that provide the test values received from the test data register circuits as power-on-reset output signals during the test.

In Example 15, the integrated circuit of any one of Examples 9-14 may optionally include, wherein the integrated circuit is a configurable integrated circuit comprising one of a monolithic die, multiple disaggregated dies, three dimensional dies, or 2.5 dimensional dies coupled through an interposer.

Example 16 is a method for testing an integrated circuit during a power-on-reset of the integrated circuit, the method comprising: generating first power-on-reset values based on first supply voltages using functional power-on-reset detector circuits in the integrated circuit; resetting test register circuits in the integrated circuit in response to a first power-on-reset signal generated by a test power-on-reset detector circuit in the integrated circuit; configuring multiplexer circuits in the integrated circuit to output the first power-on-reset values as second power-on-reset signals based on first selection values stored in the test register circuits; and configuring the multiplexer circuits to output second power-on-reset values stored in the test register circuits as the second power-on-reset signals based on second selection values stored in the test register circuits.

In Example 17, the method of Example 16 further comprises: adjusting the first power-on-reset signal to a first voltage using the test power-on-reset detector circuit in response to a second supply voltage increasing above a first level; and adjusting the first power-on-reset signal to a second voltage using the test power-on-reset detector circuit in response to the second supply voltage decreasing below a second level that is less than the first level.

In Example 18, the method of Example 17 may optionally include, wherein the second level is less than a third level that the functional power-on-reset detector circuits compare to the second supply voltage when the second supply voltage is decreasing to determine when to adjust one of the first power-on-reset values.

In Example 19, the method of any one of Examples 16-18 further comprises: generating a trip-out signal indicative of a second supply voltage increasing above a trip-out level using a trip-out detector circuit in the test power-on-reset detector circuit; generating a trip-in signal indicative of the second supply voltage decreasing below a trip-in level that is less than the trip-out level using the trip-in detector circuit in the test power-on-reset detector circuit; and generating the first power-on-reset signal based on the trip-out signal and based on the trip-in signal.

In Example 20, the method of any one of Examples 16-19 may optionally include, wherein the multiplexer circuits are configured to output the second power-on-reset values stored in the test register circuits during a low voltage test or debugging of the integrated circuit.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. A bandgap reference voltage detector circuit comprising:
an amplifier circuit that amplifies a difference between a first voltage and a second voltage as offset by a first voltage skew to control a current in the bandgap reference voltage detector circuit that affects the first voltage and the second voltage; and
a comparator circuit that compares the first voltage to the second voltage as offset by a second voltage skew to generate a third voltage that indicates when a bandgap reference voltage is stable across variations in a process, a supply voltage, and a temperature of the bandgap reference voltage detector circuit.

2. The bandgap reference voltage detector circuit of claim 1, wherein the first voltage skew in the amplifier circuit causes the first voltage to differ from the second voltage after the third voltage indicates that the bandgap reference voltage is stable.

3. The bandgap reference voltage detector circuit of claim 1, wherein the third voltage generated by the comparator circuit changes from a first level to a second level a delay after the first voltage and the second voltage are equal, and wherein the delay is caused by the second voltage skew of the comparator circuit.

4. The bandgap reference voltage detector circuit of claim 1, wherein the comparator circuit causes the third voltage to indicate when the bandgap reference voltage is stable after a power-on-reset in an integrated circuit.

5. The bandgap reference voltage detector circuit of claim 1, wherein the bandgap reference voltage detector circuit is a power-on-reset detector circuit that indicates when the supply voltage provided to a bandgap reference voltage generator circuit and to the bandgap reference voltage detector circuit reaches a nominal value.

6. The bandgap reference voltage detector circuit of claim 1, wherein the bandgap reference voltage detector circuit is in a configurable integrated circuit.

7. The bandgap reference voltage detector circuit of claim 6, wherein the configurable integrated circuit comprises one of a monolithic die, multiple disaggregated dies, three dimensional dies, or 2.5 dimensional dies coupled through an interposer.

8. The bandgap reference voltage detector circuit of claim 1, wherein the bandgap reference voltage detector circuit enables circuitry in an integrated circuit that uses the bandgap reference voltage in response to the third voltage.

9. An integrated circuit comprising a test power-on-reset detector circuit, wherein the test power-on-reset detector circuit comprises:
a trip-out detector circuit that generates a trip-out signal indicative of a supply voltage increasing above a trip-out level;
a trip-in detector circuit that generates a trip-in signal indicative of the supply voltage decreasing below a trip-in level that is less than the trip-out level; and
a latch circuit that stores values of the trip-out signal and of the trip-in signal to generate a power-on-reset signal during a test of the integrated circuit.

10. The integrated circuit of claim 9, wherein the trip-out detector circuit comprises a transistor and resistors coupled between the transistor and a supply rail at the supply voltage, wherein a gate of the transistor is coupled between the resistors, and wherein the trip-out signal is generated based on a voltage at a node between the transistor and the resistors.

11. The integrated circuit of claim 9, wherein the trip-in detector circuit comprises a transistor and resistors coupled between the transistor and a supply rail at the supply voltage, wherein a gate of the transistor is coupled to the supply rail, and wherein the trip-in signal is generated based on a voltage at a node between the transistor and the resistors.

12. The integrated circuit of claim 9 further comprising:
functional power-on-reset detector circuits that generate power-on-reset values based on additional supply voltages in the integrated circuit;
register circuits accessible through test inputs, wherein the register circuits are power-on-reset by the power-on-reset signal generated by the test power-on-reset detector circuit; and
multiplexer circuits that are configurable to select and output either the power-on-reset values or output signals of the register circuits in response to selection values stored in the register circuits.

13. The integrated circuit of claim 9 further comprising:
test data register circuits configurable to store test values during the test of the integrated circuit;
shadow register circuits that are power-on-reset by the power-on-reset signal, wherein the shadow registers circuit store the test values received from the test data register circuits; and
multiplexer circuits that provide the test values received from the shadow register circuits as power-on-reset output signals during the test.

14. The integrated circuit of claim 9 further comprising:
a test access port controller circuit;
test data register circuits configurable to store test values provided by the test access port controller circuit during the test of the integrated circuit; and
multiplexer circuits that provide the test values received from the test data register circuits as power-on-reset output signals during the test.

15. The integrated circuit of claim 9, wherein the integrated circuit is a configurable integrated circuit comprising one of a monolithic die, multiple disaggregated dies, three dimensional dies, or 2.5 dimensional dies coupled through an interposer.

16. A method for testing an integrated circuit during a power-on-reset of the integrated circuit, the method comprising:
generating first power-on-reset values based on first supply voltages using functional power-on-reset detector circuits in the integrated circuit;
resetting test register circuits in the integrated circuit in response to a first power-on-reset signal generated by a test power-on-reset detector circuit in the integrated circuit;
configuring multiplexer circuits in the integrated circuit to output the first power-on-reset values as second power-on-reset signals based on first selection values stored in the test register circuits; and
configuring the multiplexer circuits to output second power-on-reset values stored in the test register circuits as the second power-on-reset signals based on second selection values stored in the test register circuits.

17. The method of claim 16 further comprising:
adjusting the first power-on-reset signal to a first voltage using the test power-on-reset detector circuit in response to a second supply voltage increasing above a first level; and
adjusting the first power-on-reset signal to a second voltage using the test power-on-reset detector circuit in response to the second supply voltage decreasing below a second level that is less than the first level.

18. The method of claim 17, wherein the second level is less than a third level that the functional power-on-reset detector circuits compare to the second supply voltage when the second supply voltage is decreasing to determine when to adjust one of the first power-on-reset values.

19. The method of claim 16 further comprising:
generating a trip-out signal indicative of a second supply voltage increasing above a trip-out level using a trip-out detector circuit in the test power-on-reset detector circuit;
generating a trip-in signal indicative of the second supply voltage decreasing below a trip-in level that is less than the trip-out level using a trip-in detector circuit in the test power-on-reset detector circuit; and
generating the first power-on-reset signal based on the trip-out signal and based on the trip-in signal.

20. The method of claim 16, wherein the multiplexer circuits are configured to output the second power-on-reset values stored in the test register circuits during a low voltage test or debugging of the integrated circuit.
